(19) United States
(12) Patent Application Publication
(10) Pub. No.: US 2024/0290837 A1
(43) Pub. Date: Aug. 29, 2024

(54) SEMICONDUCTOR DEVICE AND METHOD FOR MANUFACTURING SEMICONDUCTOR DEVICE

(71) Applicant: Mitsubishi Electric Corporation, Tokyo (JP)

(72) Inventors: Takahiro NAKATANI, Tokyo (JP); Koichi NISHI, Tokyo (JP); Fumihito MASUOKA, Tokyo (JP); Masanori TSUKUDA, Tokyo (JP)

(73) Assignee: Mitsubishi Electric Corporation, Tokyo (JP)

(21) Appl. No.: 18/410,886

(22) Filed: Jan. 11, 2024

(30) Foreign Application Priority Data
Feb. 24, 2023 (JP) 2023-027256

(51) Int. Cl. H01L 29/06; H01L 21/02; H01L 29/51

(52) U.S. Cl. CPC H01L 29/0684; H01L 21/02216; H01L 29/51

(57) ABSTRACT

Provided is a semiconductor device including a semiconductor substrate, a TEOS film, and an electrode. The semiconductor substrate has a first principal surface and a second principal surface opposite to the first principal surface. The semiconductor substrate has an active region and a termination region surrounding the active region when the second principal surface is viewed along a direction of a normal to the second principal surface. The TEOS film is disposed on a part of the second principal surface located in the active region.

### CROSS REFERENCE TO RELATED APPLICATIONS

This nonprovisional application is based on Japanese Patent Application No. 2023-027256 filed on Feb. 24, 2023, with the Japan Patent Office, the entire contents of which are hereby incorporated by reference.

### BACKGROUND OF THE INVENTION

### Field of the Invention

The present disclosure relates to a semiconductor device and a method for manufacturing a semiconductor device.

### Description of the Background Art

The semiconductor device disclosed in Japanese Patent Laying-Open No. 2018-117016 includes a semiconductor substrate, an interlayer insulating film, and a metal electrode. The semiconductor substrate has a first principal surface and a second principal surface opposite to the first principal surface. The interlayer insulating film is disposed on the second principal surface. A constituent material of the interlayer insulating film is boron phosphorus silicon glass (BPSG). The metal electrode is disposed on the interlayer insulating film.

### SUMMARY OF THE INVENTION

In the semiconductor device disclosed in Japanese Patent Laying-Open No. 2018-117016, since the constituent material of the interlayer insulating film is BPSG containing phosphorus and boron, the interlayer insulating film is high in hygroscopicity and tends to contain moisture. As a result, the semiconductor device disclosed in Japanese Patent Laying-Open No. 2018-117016 has a possibility that the metal electrode disposed on the interlayer insulating film may be corroded by moisture.

The present disclosure has been made in view of the above-described problem with the related art. More specifically, the present disclosure provides a semiconductor device capable of inhibiting corrosion of an electrode disposed on an interlayer insulating film.

A semiconductor device of the present disclosure includes a semiconductor substrate, a TEOS film, and an electrode. The semiconductor substrate has a first principal surface and a second principal surface opposite to the first principal surface. The semiconductor substrate has an active region and a termination region surrounding the active region when the second principal surface is viewed along a direction of a normal to the second principal surface. The TEOS film is disposed on a part of the second principal surface located in the active region.

The foregoing and other objects, features, aspects, and advantages of the present invention will become more apparent from the following detailed description of the present invention when taken in conjunction with the accompanying drawings.

### BRIEF DESCRIPTION OF THE DRAWINGS

FIG. 1 is a cross-sectional view of a semiconductor device 100.

FIG. 2 is a diagram illustrating a process of manufacturing semiconductor device 100.

FIG. 3 is a cross-sectional view for describing an ion implantation process S2.

FIG. 4 is a cross-sectional view for describing a trench forming process S3.

FIG. 5 is a cross-sectional view for describing a gate insulating film forming process S4.

FIG. 6 is a cross-sectional view for describing a gate forming process S5.

FIG. 7 is a cross-sectional view for describing an interlayer insulating film forming process S6.

FIG. 8 is a cross-sectional view for describing a contact hole forming process S7.

FIG. 9 is a cross-sectional view for describing a first electrode forming process S8.

FIG. 10 is a cross-sectional view for describing a semi-insulating film forming process S9.

FIG. 11 is a cross-sectional view of a semiconductor device 100A.

FIG. 12 is a cross-sectional view of a semiconductor device 100B.

FIG. 13 is a cross-sectional view of a semiconductor device 100C.

FIG. 14 is a cross-sectional view of a semiconductor device 100D.

FIG. 15A is a simulation result of electric field distribution in a case where a thickness T for semiconductor device 100D is 800 nm.

FIG. 15B is a simulation result of electric field distribution in a case where thickness T for semiconductor device 100D is 1200 nm.

### DESCRIPTION OF THE PREFERRED EMBODIMENTS

Hereinafter, embodiments of the present disclosure will be described in detail with reference to drawings. In the following drawings, the same or corresponding parts are denoted by the same reference numerals to avoid the description from being redundant.

### First Embodiment

A semiconductor device according to a first embodiment will be described.

The semiconductor device according to the first embodiment is referred to as semiconductor device 100.

### (Configuration of Semiconductor Device 100)

Hereinafter, the configuration of semiconductor device 100 will be described.

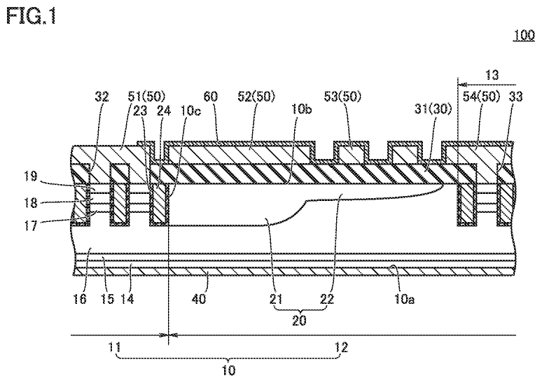

FIG. 1 is a cross-sectional view of semiconductor device 100. As illustrated in FIG. 1, semiconductor device 100 includes a semiconductor substrate 10, a gate insulating film 23, a gate 24, an interlayer insulating film 30, an electrode 40, an electrode 50, and a semi-insulating film 60. Semiconductor device 100 is, for example, an insulated gate bipolar transistor (IGBT).

Semiconductor substrate 10 includes, for example, monocrystalline silicon. Semiconductor substrate 10 has a first principal surface 10a and a second principal surface 10b. Second principal surface 10b is a surface opposite to first principal surface 10a.

Semiconductor substrate 10 has an active region 11 and a termination region 12 as viewed from above (when second principal surface 10b is viewed along a direction of a normal to second principal surface 10b). Termination region 12 surrounds active region 11 as viewed from above. Termination region 12 has a channel stopper region 13. Channel stopper region 13 is located at an outer peripheral portion of termination region 12 as viewed from above.

A trench 10c is formed at a part of second principal surface 10b located in active region 11. Trench 10c extends from second principal surface 10b toward first principal surface 10a. Trench 10c may be further formed at a part of second principal surface 10b located in channel stopper region 13.

Semiconductor substrate 10 has a collector region 14, a buffer region 15, a drift region 16, a carrier storage region 17, a base region 18, and an emitter region 19.

Collector region 14 is disposed on first principal surface 10a. Buffer region 15 is disposed on collector region 14. Drift region 16 is disposed on buffer region 15. Carrier storage region 17 is disposed on a part of drift region 16 located in active region 11. Carrier storage region 17 may be further disposed on a part of drift region 16 located in channel stopper region 13. Base region 18 is disposed on carrier storage region 17. Emitter region 19 is disposed on base region 18 to serve as second principal surface 10b.

Buffer region 15, drift region 16, carrier storage region 17, and collector region 14 are of a first conductivity type. Collector region 14 and base region 18 are of a second conductivity type. The second conductivity type is a conductivity type opposite to the first conductivity type. For example, the first conductivity type is an n-type, and the second conductivity type is a p-type.

Semiconductor substrate 10 further has a well region 20. Well region 20 is disposed on second principal surface 10b located in termination region 12. Well region 20 is of the second conductivity type. Well region 20 has a relaxation region 21 and a reduced surface field (RESURF) region 22. RESURF region 22 is located outside relaxation region 21 as viewed from above. A dopant concentration of relaxation region 21 decreases from a side adjacent to active region 11 toward a side adjacent to RESURF region 22. A dopant concentration of RESURF region 22 decreases from a side adjacent to relaxation region 21 toward a side adjacent to channel stopper region 13.

Drift region 16, carrier storage region 17, base region 18, and emitter region 19 are exposed from a side wall surface of trench 10c. That is, a bottom of trench 10c reaches drift region 16. Base region 18 located on the side wall surface of trench 10c serves as a channel region.

Gate insulating film 23 is disposed on the side wall surface of trench 10c and the bottom surface of trench 10c. A constituent material of gate insulating film 23 is, for example, silicon oxide. Gate 24 is embedded in trench 10c. That is, gate 24 faces the channel region with gate insulating film 23 interposed between gate 24 and the channel region. Therefore, when a voltage is applied to gate 24, the channel region is inverted, and the IGBT is turned on. A constituent material of gate 24 is, for example, polycrystalline silicon containing a dopant.

Interlayer insulating film 30 is disposed on second principal surface 10b. In semiconductor device 100, interlayer insulating film 30 includes a TEOS film 31. A constituent material of TEOS film 31 is tetraethyl orthosilicate (TEOS). TEOS film 31 is substantially free of impurities such as phosphorus or boron. A contact hole 32 and a contact hole 33 are formed in interlayer insulating film 30. Contact hole 32 and contact hole 33 extend through interlayer insulating film 30 along a thickness direction. Emitter region 19 located in active region 11 is exposed from contact hole 32, and emitter region 19 located in channel stopper region 13 is exposed from contact hole 33.

Electrode 40 is disposed on first principal surface 10a. Electrode 40 is a collector electrode. A constituent material of electrode 40 is, for example, an aluminum-silicon alloy. Electrode 50 is disposed on interlayer insulating film 30 (TEOS film 31). Electrode 50 includes an emitter electrode 51, a gate electrode 52, a field plate electrode 53, and a channel stopper electrode 54. A constituent material of electrode 50 is, for example, an aluminum-silicon alloy.

Emitter electrode 51 is disposed on interlayer insulating film 30 disposed on a part of second principal surface 10b located in active region 11. Further, emitter electrode 51 is embedded in contact hole 32 to electrically connect to emitter region 19. Gate electrode 52 is disposed on interlayer insulating film 30 disposed on a part of second principal surface 10b located in termination region 12. Although not illustrated, gate electrode 52 is embedded in a contact hole formed in interlayer insulating film 30 other than contact hole 32 and contact hole 33 to electrically connect to gate 24.

Field plate electrode 53 is disposed on the interlayer insulating film 30 disposed on a part of second principal surface 10b located in termination region 12. More specifically, field plate electrode 53 faces RESURF region 22 with interlayer insulating film 30 interposed between field plate electrode 53 and RESURF region 22. Channel stopper electrode 54 is disposed on interlayer insulating film 30 disposed on a part of second principal surface 10b located in channel stopper region 13. Further, channel stopper electrode 54 is embedded in contact hole 33 to electrically connect to emitter region 19.

Semi-insulating film 60 is disposed on interlayer insulating film 30 so as to cover gate electrode 52, field plate electrode 53, and channel stopper electrode 54. Semi-insulating film 60 may cover a part of emitter electrode 51. A constituent material of semi-insulating film 60 is semi-insulating silicon nitride (SinSiN).

### (Method for Manufacturing Semiconductor Device 100)

Hereinafter, a method for manufacturing semiconductor device 100 will be described.

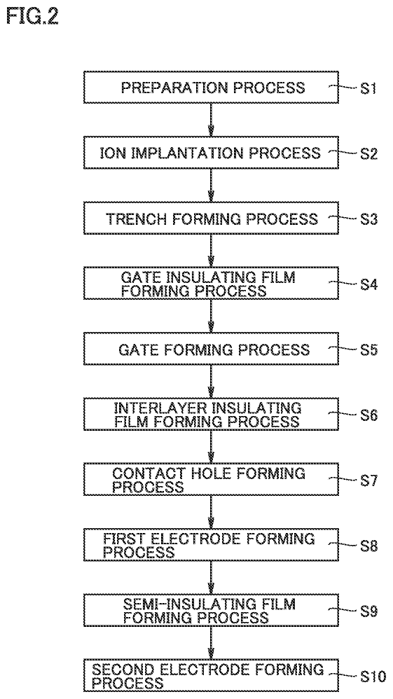

FIG. 2 is a diagram illustrating a process of manufacturing semiconductor device 100. As illustrated in FIG. 2, the method for manufacturing semiconductor device 100 includes a preparation process S1, an ion implantation process S2, a trench forming process S3, a gate insulating film forming process S4, a gate forming process S5, an interlayer insulating film forming process S6, a contact hole forming process S7, a first electrode forming process S8, a semi-insulating film forming process S9, and a second electrode forming process S10.

In preparation process S1, semiconductor substrate 10 is prepared. After preparation process S1 is performed, ion implantation process S2 is performed.

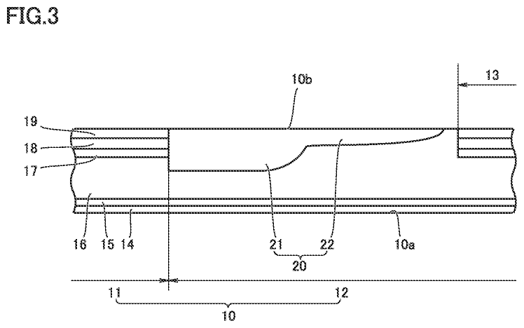

FIG. 3 is a cross-sectional view for describing ion implantation process S2. As illustrated in FIG. 3, in ion implantation process S2, ion implantation is performed to form collector region 14, buffer region 15, drift region 16, carrier storage region 17, base region 18, emitter region 19, and well region 20. After ion implantation process S2 is performed, trench forming process S3 is performed.

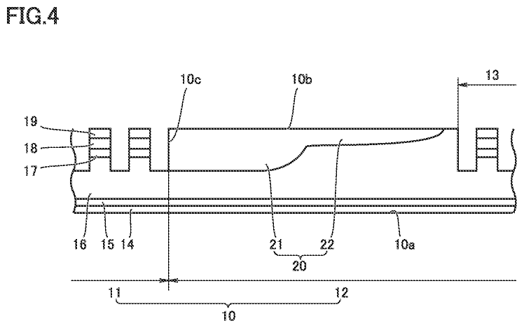

FIG. 4 is a cross-sectional view for describing trench forming process S3. As illustrated in FIG. 4, in trench forming process S3, trench 10c is formed. In trench forming process S3, first, a hard mask is formed on second principal surface 10b. The hard mask includes, for example, a silicon oxide film and a silicon nitride film disposed on the silicon oxide film. Second, patterning is performed on the hard mask. The patterning is performed on the hard mask by etching using, as a mask, a resist pattern formed on the hard mask by photolithography. The hard mask after being subjected to the patterning has an opening. A part of second principal surface 10b where trench 10c is to be formed is exposed from the opening of the hard mask.

Third, anisotropic dry etching is performed on semiconductor substrate 10 exposed from the hard mask. As a result, trench 10c is formed. Note that after trench 10c is formed, the hard mask is removed. After trench forming process S3 is performed, gate insulating film forming process S4 is performed.

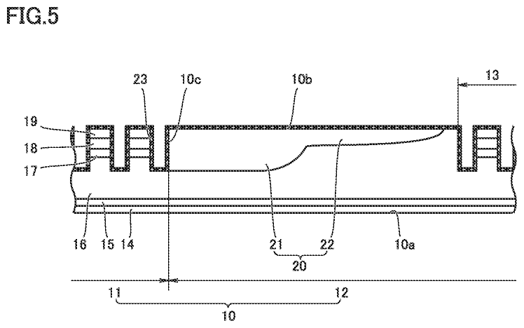

FIG. 5 is a cross-sectional view for describing gate insulating film forming process S4. As illustrated in FIG. 5, in gate insulating film forming process S4, gate insulating film 23 is formed. For example, second principal surface 10b is thermally oxidized to form gate insulating film 23. After gate insulating film forming process S4, gate forming process S5 is performed.

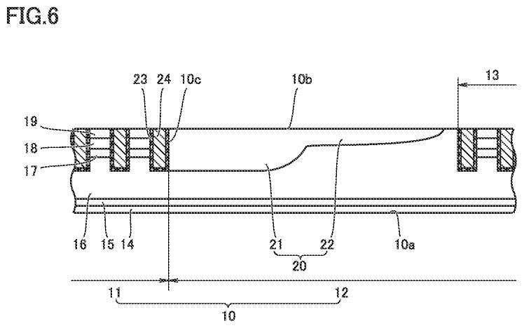

FIG. 6 is a cross-sectional view for describing gate forming process S5. As illustrated in FIG. 6, in gate forming process S5, gate 24 is embedded. In gate forming process S5, first, the constituent material of gate 24 is embedded in trench 10c by, for example, a chemical vapor deposition (CVD) method. Second, the constituent material of gate 24 protruding from trench 10c is removed by, for example, a chemical mechanical polishing (CMP) method. After gate forming process S5 is performed, interlayer insulating film forming process S6 is performed.

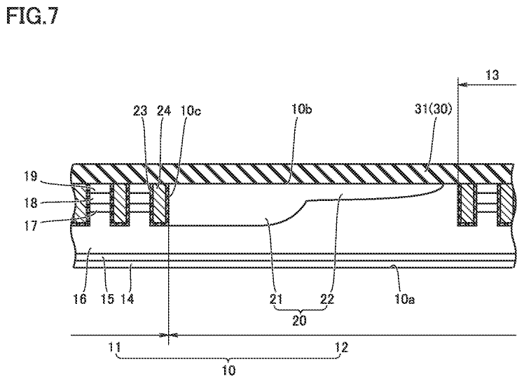

FIG. 7 is a cross-sectional view for describing interlayer insulating film forming process S6. As illustrated in FIG. 7, in interlayer insulating film forming process S6, interlayer insulating film 30 (TEOS film 31) is formed by, for example, a CVD method. After interlayer insulating film forming process S6 is performed, contact hole forming process S7 is performed.

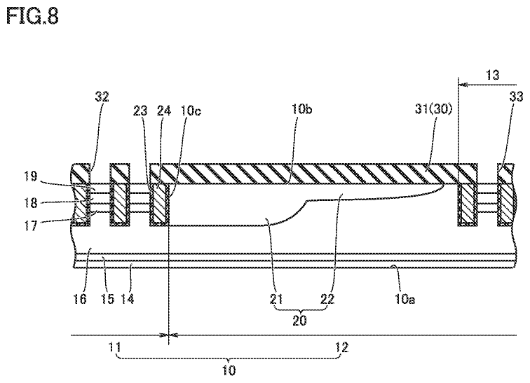

FIG. 8 is a cross-sectional view for describing contact hole forming process S7. As illustrated in FIG. 8, in contact hole forming process S7, contact hole 32 and contact hole 33 are formed. In contact hole forming process S7, first, a resist pattern is formed on interlayer insulating film 30 by photolithography. The resist pattern has an opening at a position where contact hole 32 and contact hole 33 are formed.

Second, dry etching is performed, using the resist pattern as a mask, on interlayer insulating film 30 exposed from the opening of the resist pattern to form contact hole 32 and contact hole 33 in interlayer insulating film 30. Note that, although not illustrated, when contact hole 32 and contact hole 33 are formed, a contact hole in which gate 24 is embedded is also formed. After contact hole forming process S7 is performed, first electrode forming process S8 is performed.

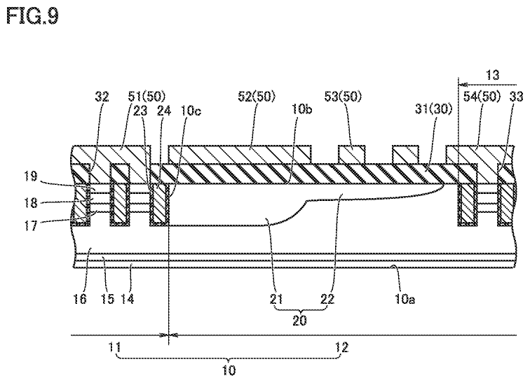

FIG. 9 is a cross-sectional view for describing first electrode forming process S8. As illustrated in FIG. 9, in first electrode forming process S8, electrode 50 (emitter electrode 51, gate electrode 52, field plate electrode 53, channel stopper electrode 54) is formed. In first electrode forming process S8, first, the constituent material of electrode 50 is deposited on interlayer insulating film 30. At this time, the constituent material of electrode 50 is also embedded in contact hole 32 and contact hole 33. The constituent material of electrode 50 is preferably deposited by sputtering of the constituent material of electrode 50 with semiconductor substrate 10 heated to 400° C. or higher.

Second, patterning is performed on the deposited constituent material of electrode 50. The patterning is performed on the deposited constituent material of electrode 50 by dry etching using, as a mask, a resist pattern formed on the deposited constituent material of deposited electrode 50. The resist pattern is formed by, for example, photolithography. After first electrode forming process S8 is performed, semi-insulating film forming process S9 is performed.

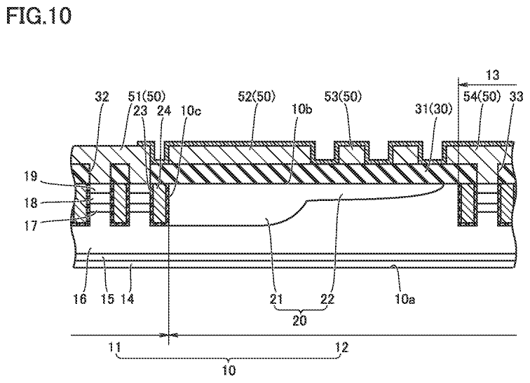

FIG. 10 is a cross-sectional view for describing semi-insulating film forming process S9. As illustrated in FIG. 10, in semi-insulating film forming process S9, semi-insulating film 60 is formed by, for example, a CVD method. After semi-insulating film forming process S9 is performed, second electrode forming process S10 is performed. In second electrode forming process S10, for example, sputtering is performed on first principal surface 10a to form electrode 40. As a result, the structure of semiconductor device 100 illustrated in FIG. 1 is formed.

### (Effects Produced by Semiconductor Device 100)

Hereinafter, effects produced by semiconductor device 100 will be described.

In a case where interlayer insulating film 30 includes BPSG, interlayer insulating film 30 becomes high in hygroscopicity and tends to contain moisture. As a result, electrode 50 disposed on interlayer insulating film 30 may be corroded by moisture.

In semiconductor device 100, however, interlayer insulating film 30 includes TEOS film 31, and TEOS film 31 includes TEOS substantially free of phosphorus or boron, thereby making interlayer insulating film 30 low in hygroscopicity. It is therefore possible for semiconductor device 100 to inhibit corrosion, caused by moisture, of the electrode disposed on interlayer insulating film 30.

In a case where interlayer insulating film 30 includes BPSG, embedding in a step portion or a groove is easily performed, and it is therefore possible to planarize the surface of interlayer insulating film 30. On the other hand, in a case where interlayer insulating film 30 includes the TEOS film, irregularities tend to remain on the surface of interlayer insulating film 30. In the method for manufacturing semiconductor device 100, however, when first electrode forming process S8 is performed, sputtering is performed with semiconductor substrate 10 heated to 400° C. or higher, so that the constituent material of electrode 50 is deposited on interlayer insulating film 30 while reflowing, and it is therefore possible to reduce the influence of irregularities remaining on the surface of interlayer insulating film 30 (that is, a possibility that the influence of irregularities of the surface of interlayer insulating film 30 may remain on the surface of electrode 50).

### (Modification)

The example where semiconductor device 100 is an IGBT has been described above, but semiconductor device 100 is not limited to the example. Semiconductor device 100 may be a metal oxide semiconductor field effect transistor (MOSFET) or a diode.

### Second Embodiment

A semiconductor device according to a second embodiment will be described. The semiconductor device according to the second embodiment is referred to as semiconductor device 100A. Here, differences from semiconductor device 100 will be mainly described to avoid the description from being redundant.

### (Configuration of Semiconductor Device 100A)

Hereinafter, the configuration of semiconductor device 100A will be described.

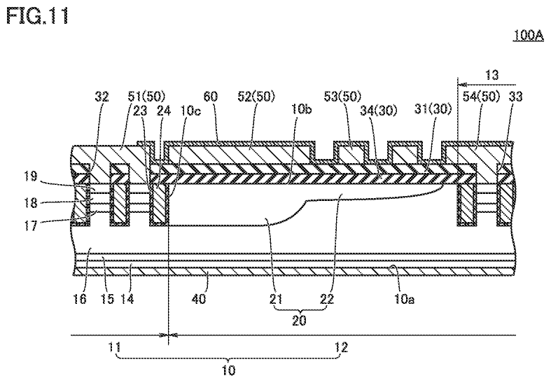

FIG. 11 is a cross-sectional view of a semiconductor device 100A. As illustrated in FIG. 11, semiconductor device 100A includes semiconductor substrate 10, gate insulating film 23, gate 24, interlayer insulating film 30, electrode 40, electrode 50, and semi-insulating film 60. In this respect, semiconductor device 100A is identical in configuration to semiconductor device 100. In semiconductor device 100A, interlayer insulating film 30 further includes a thermal oxide film 34. Thermal oxide film 34 is interposed between TEOS film 31 and second principal surface 10b. A constituent material of thermal oxide film 34 is, for example, silicon oxide. In this respect, semiconductor device 100A is different in configuration from semiconductor device 100.

Note that thermal oxide film 34 is formed by thermal oxidation of second principal surface 10b located in termination region 12 before TEOS film 31 is formed in interlayer insulating film forming process S6. A heat treatment temperature when thermal oxide film 34 is formed is, for example, higher than or equal to 1000° C. A thickness of thermal oxide film 34 is preferably greater than or equal to 800 nm and less than or equal to 1200 nm.

### (Effects Produced by Semiconductor Device 100A)

Hereinafter, effects produced by semiconductor device 100A will be described.

In termination region 12, electric field intensity tends to be high. In semiconductor device 100A, however, thermal oxide film 34 is formed in addition to TEOS film 31, so that the electric field in termination region 12 is relaxed as compared with semiconductor device 100.

### Third Embodiment

A semiconductor device according to a third embodiment will be described. The semiconductor device according to the third embodiment is referred to as semiconductor device 100B. Here, differences from semiconductor device 100A will be mainly described to avoid the description from being redundant.

### (Configuration of Semiconductor Device 100B)

Hereinafter, the configuration of semiconductor device 100B will be described.

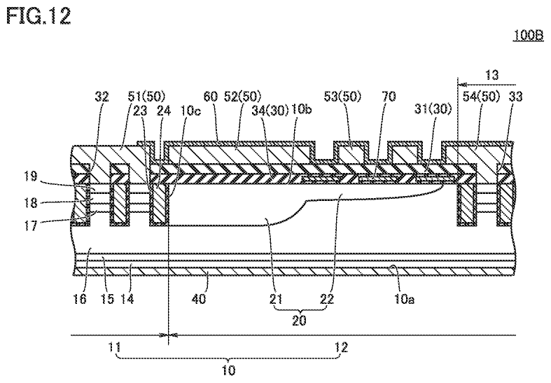

FIG. 12 is a cross-sectional view of semiconductor device 100B. As illustrated in FIG. 12, semiconductor device 100B includes semiconductor substrate 10, gate insulating film 23, gate 24, interlayer insulating film 30, electrode 40, electrode 50, and semi-insulating film 60. Further, in semiconductor device 100B, interlayer insulating film 30 includes TEOS film 31 and thermal oxide film 34. In these respects, semiconductor device 100B is identical in configuration to semiconductor device 100A.

Semiconductor device 100B further includes a plurality of conductor portions 70. The plurality of conductor portions 70 are arranged in thermal oxide film 34. The plurality of conductor portions 70 are arranged apart from each other. The plurality of conductor portions 70 are located between field plate electrode 53 and RESURF region 22. Conductor portions 70 are electrically floating. A constituent material of conductor portions 70 is a conductor. The constituent material of conductor portions 70 is, for example, polycrystalline silicon. In these respects, semiconductor device 100B is different in configuration from semiconductor device 100A.

### (Effects Produced by Semiconductor Device 100B)

Hereinafter, effects produced by semiconductor device 100B will be described.

In semiconductor device 100B, conductor portions 70 are arranged in thermal oxide film 34, so that the electric field in termination region 12 is further relaxed as compared with semiconductor device 100A.

### Fourth Embodiment

A semiconductor device according to a fourth embodiment will be described. The semiconductor device according to the fourth embodiment is referred to as semiconductor device 100C. Here, differences from semiconductor device 100B will be mainly described to avoid the description from being redundant.

### (Configuration of Semiconductor Device 100C)

Hereinafter, the configuration of semiconductor device 100C will be described.

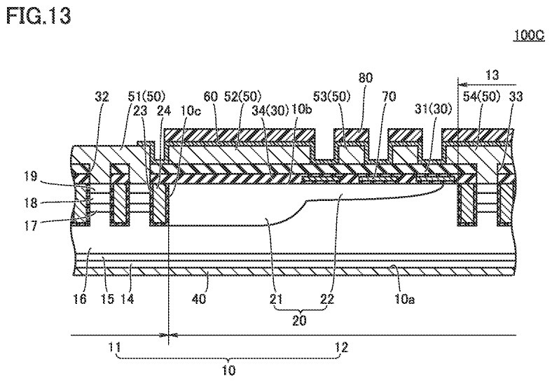

FIG. 13 is a cross-sectional view of semiconductor device 100C. As illustrated in FIG. 13, semiconductor device 100C includes semiconductor substrate 10, gate insulating film 23, gate 24, interlayer insulating film 30, electrode 40, electrode 50, semi-insulating film 60, and the plurality of conductor portions 70. Further, in semiconductor device 100C, interlayer insulating film 30 includes TEOS film 31 and thermal oxide film 34. In these respects, semiconductor device 100C is identical in configuration to semiconductor device 100B.

Semiconductor device 100C further includes an organic insulating film 80. A constituent material of organic insulating film 80 is, for example, an organic material such as polyimide. Organic insulating film 80 is disposed on a part of semi-insulating film 60 disposed on gate electrode 52, field plate electrode 53, and channel stopper electrode 54. A thickness of organic insulating film 80 is, for example, greater than or equal to 5 μm and less than or equal to 30 μm. In these respects, semiconductor device 100C is different in configuration from semiconductor device 100B.

### (Effects Produced by Semiconductor Device 100C)

Hereinafter, effects produced by semiconductor device 100C will be described.

In semiconductor device 100C, organic insulating film 80 is disposed on a part of semi-insulating film 60 disposed on gate electrode 52, field plate electrode 53, and channel stopper electrode 54. That is, in semiconductor device 100C, organic insulating film 80 is disposed on a part of semi-insulating film 60 other than a step part. The presence of organic insulating film 80 allows an increase in adhesion to an encapsulation resin (not illustrated) in which semiconductor device 100C is encapsulated. Therefore, semiconductor device 100C makes it possible to increase adhesion to the encapsulation resin in which semiconductor device 100C is encapsulated without worsening the electric field concentration at the step part of semi-insulating film 60.

### Fifth Embodiment

A semiconductor device according to a fifth embodiment will be described. The semiconductor device according to the fifth embodiment is referred to as semiconductor device 100D. Here, differences from semiconductor device 100C will be mainly described to avoid the description from being redundant.

### (Configuration of Semiconductor Device 100D)

Hereinafter, the configuration of semiconductor device 100D will be described.

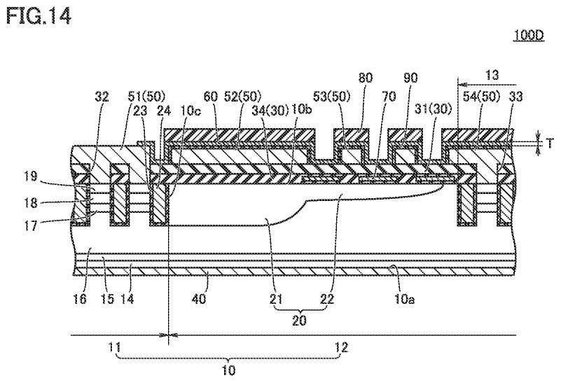

FIG. 14 is a cross-sectional view of semiconductor device 100D. As illustrated in FIG. 14, semiconductor device 100D includes semiconductor substrate 10, gate insulating film 23, gate 24, interlayer insulating film 30, electrode 40, electrode 50, semi-insulating film 60, the plurality of conductor portions 70, and organic insulating film 80. Further, in semiconductor device 100D, interlayer insulating film 30 includes TEOS film 31 and thermal oxide film 34. In these respects, semiconductor device 100D is identical in configuration to semiconductor device 100C.

Semiconductor device 100D further includes a buffer film 90. A constituent material of buffer film 90 is, for example, silicon oxide. Buffer film 90 is formed by, for example, a CVD method. Buffer film 90 is lower in hardness than semi-insulating film 60. Buffer film 90 is interposed between gate electrode 52 and semi-insulating film 60, between field plate electrode 53 and semi-insulating film 60, and between channel stopper electrode 54 and semi-insulating film 60. In these respects, semiconductor device 100D is different in configuration from semiconductor device 100C.

A thickness of semi-insulating film 60 is denoted as thickness T. In semiconductor device 100D, thickness T is preferably greater than or equal to 1200 nm.

### (Effects Produced by Semiconductor Device 100D)

Hereinafter, effects produced by semiconductor device 100D will be described.

In semiconductor device 100D, buffer film 90 is interposed between gate electrode 52 and semi-insulating film 60, between field plate electrode 53 and semi-insulating film 60, and between channel stopper electrode 54 and semi-insulating film 60, and buffer film 90 is lower in hardness than semi-insulating film 60, so that external stress applied to semi-insulating film 60 is reduced.

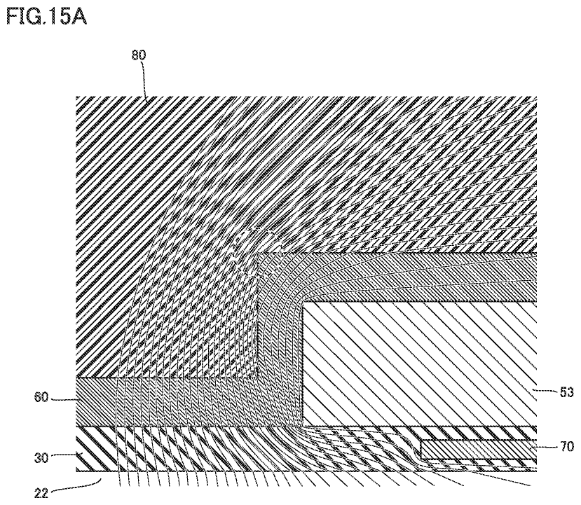

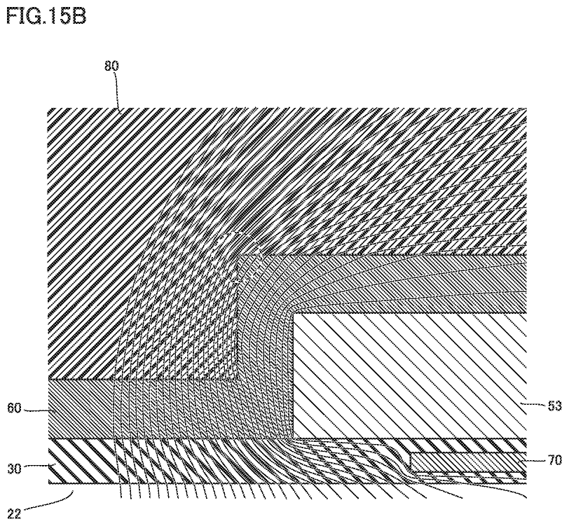

FIG. 15A is a simulation result of electric field distribution in a case where thickness T for semiconductor device 100D is 800 nm. FIG. 15B is a simulation result of electric field distribution in a case where thickness T for semiconductor device 100D is 1200 nm. As illustrated in FIGS. 15A and 15B, in the case where thickness Tis 1200 nm, the electric field concentration at a corner portion (portion indicated by a dotted line in FIGS. 15A and 15B) of the surface of semi-insulating film 60 is reduced as compared with the case where thickness Tis 800 nm. Therefore, semiconductor device 100D makes it possible to inhibit the occurrence of a crack in semi-insulating film 60 due to the electric field.

### APPENDIX

Aspects of the present disclosure will be described collectively as an appendix.

### Appendix 1

A semiconductor device including:
a semiconductor substrate;
a TEOS film; and
an electrode, in which
the semiconductor substrate has a first principal surface and a second principal surface opposite to the first principal surface,
the semiconductor substrate has an active region and a termination region surrounding the active region when the second principal surface is viewed along a direction of a normal to the second principal surface, and
the TEOS film is disposed on a part of the second principal surface located in the active region.

### Appendix 2

The semiconductor device according to appendix 1, further including a thermal oxide film interposed between the second principal surface and the TEOS film.

### Appendix 3

The semiconductor device according to appendix 2, further including a conductor portion disposed in the thermal oxide film, in which the conductor portion is electrically floating.

### Appendix 4

The semiconductor device according to any one of appendixes 1 to 3, further including a semi-insulating film disposed on the TEOS film to cover the electrode.

### Appendix 5

The semiconductor device according to appendix 4, in which a thickness of the semi-insulating film is greater than or equal to 1.2 μm.

### Appendix 6

The semiconductor device according to appendix 4 or 5, further including an organic insulating film disposed on a part of the semi-insulating film disposed on the electrode.

### Appendix 7

The semiconductor device according to any one of appendixes 4 to 6, further including a buffer film interposed between the electrode and the semi-insulating film, in which the buffer film is lower in hardness than the semi-insulating film.

### Appendix 8

A method for manufacturing a semiconductor device, including:
preparing a semiconductor substrate having a first principal surface and a second principal surface opposite to the first principal surface, the semiconductor substrate having an active region and a termination region surrounding the active region when the second principal surface is viewed along a direction of a normal to the second principal surface;
forming a TEOS film on a part of the second principal surface located in the active region; and
forming an electrode on the TEOS film, the electrode being formed by sputtering of a constituent material of the electrode with the semiconductor substrate heated to 400° C. or higher.

Although the embodiments of the present invention have been described, it should be understood that the embodiments disclosed herein are illustrative in all respects and not restrictive. The scope of the present invention is interpreted by the terms of the appended claims, and the present invention is intended to include the claims, equivalents of the claims, and all modifications within the scope.

What is claimed is:

1. A semiconductor device comprising:
a semiconductor substrate;
a TEOS film; and
an electrode, wherein
the semiconductor substrate has a first principal surface and a second principal surface opposite to the first principal surface,
the semiconductor substrate has an active region and a termination region surrounding the active region when the second principal surface is viewed along a direction of a normal to the second principal surface, and
the TEOS film is disposed on a part of the second principal surface located in the active region.

2. The semiconductor device according to claim 1, further comprising a thermal oxide film interposed between the second principal surface and the TEOS film.

3. The semiconductor device according to claim 2, further comprising a conductor portion disposed in the thermal oxide film, wherein
the conductor portion is electrically floating.

4. The semiconductor device according to claim 1, further comprising a semi-insulating film disposed on the TEOS film to cover the electrode.

5. The semiconductor device according to claim 2, further comprising a semi-insulating film disposed on the TEOS film to cover the electrode.

6. The semiconductor device according to claim 3, further comprising a semi-insulating film disposed on the TEOS film to cover the electrode.

7. The semiconductor device according to claim 4, wherein
a thickness of the semi-insulating film is greater than or equal to 1.2 μm.

8. The semiconductor device according to claim 5, wherein
a thickness of the semi-insulating film is greater than or equal to 1.2 μm.

9. The semiconductor device according to claim 6, wherein
a thickness of the semi-insulating film is greater than or equal to 1.2 μm.

10. The semiconductor device according to claim 4, further comprising an organic insulating film disposed on a part of the semi-insulating film disposed on the electrode.

11. The semiconductor device according to claim 5, further comprising an organic insulating film disposed on a part of the semi-insulating film disposed on the electrode.

12. The semiconductor device according to claim 6, further comprising an organic insulating film disposed on a part of the semi-insulating film disposed on the electrode.

13. The semiconductor device according to claim 4, further comprising a buffer film interposed between the electrode and the semi-insulating film, wherein
the buffer film is lower in hardness than the semi-insulating film.

14. The semiconductor device according to claim 5, further comprising a buffer film interposed between the electrode and the semi-insulating film, wherein
the buffer film is lower in hardness than the semi-insulating film.

15. The semiconductor device according to claim 6, further comprising a buffer film interposed between the electrode and the semi-insulating film, wherein
the buffer film is lower in hardness than the semi-insulating film.

16. A method for manufacturing a semiconductor device, comprising:
preparing a semiconductor substrate having a first principal surface and a second principal surface opposite to the first principal surface, the semiconductor substrate having an active region and a termination region surrounding the active region when the second principal surface is viewed along a direction of a normal to the second principal surface;
forming a TEOS film on a part of the second principal surface located in the active region; and
forming an electrode on the TEOS film,
the electrode being formed by sputtering of a constituent material of the electrode with the semiconductor substrate heated to 400° C. or higher.
